(19) United States
(12) Patent Application Publication
(10) Pub. No.: US 2025/0318210 A1
(43) Pub. Date: Oct. 9, 2025

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Junpei HISADA, Nonoichi (JP); Noboru MATSUDA, Kanazawa (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 18/825,276

(22) Filed: Sep. 5, 2024

(30) Foreign Application Priority Data
Apr. 4, 2024 (JP) 2024-061084

(51) Int. Cl. H01L 29/06; H01L 29/40; H01L 29/66; H01L 29/78

(52) U.S. Cl. CPC H10D 62/102; H10D 30/665; H10D 30/668; H10D 62/124; H10D 64/117; H10D 30/0297

(57) ABSTRACT

A semiconductor device according to an embodiment includes a semiconductor layer, a first electrode, a second electrode, a first semiconductor region of a first conductivity type, a second semiconductor region of a second conductivity type, and a third semiconductor region of the first conductivity type. The semiconductor layer includes a first portion and a second portion. The first portion includes a third electrode provided in the second semiconductor region via an insulating region, and a fourth semiconductor region of the second conductivity type provided in the second semiconductor region. The second portion includes a conductive connection part having a length in a third direction smaller than that of the third electrode; and a fifth semiconductor region of the second conductivity type that is provided in the second semiconductor region, and has a length, in the third direction, of the fifth semiconductor region larger than that of the fourth semiconductor region.

### CROSS-REFERENCE TO RELATED APPLICATIONS

This application is based upon and claims the benefit of priority from the prior Japanese Patent Application No. 2024-061084, filed on Apr. 4, 2024; the entire contents of which are incorporated herein by reference.

### FIELD

Embodiments described herein relate generally to a semiconductor device.

### BACKGROUND

In a power metal oxide semiconductor field effect transistor (MOSFET) and the like, it is required to improve avalanche breakdown tolerance while suppressing a variation the threshold voltage of each product.

As a method of improving the avalanche breakdown tolerance, it is conceivable to suppress the operation of a parasitic bipolar in a MOSFET. Since the parasitic bipolar is easily operated by minority carriers accumulated in a base region, the avalanche breakdown tolerance can be improved by discharging the minority carriers accumulated in the base region to the outside. For example, a contact trench that penetrates a source region to reach the base region is formed, and a high-concentration region, such as a p⁺-type semiconductor region, is formed at the bottom of the trench.

However, if the position of the trench is shifted from the intended position in the manufacturing process of the MOSFET, the high-concentration region to be formed at the bottom of the trench may approach the boundary (channel surface) between the base region and a gate insulating film, leading to a fluctuation in the threshold voltage of the MOSFET. On the other hand, if the size or the impurity concentration of the high-concentration region is limited in order to avoid a fluctuation in the threshold voltage, it becomes difficult to improve the avalanche breakdown tolerance.

### BRIEF DESCRIPTION OF THE DRAWINGS

FIG. 1 is a plan view of a semiconductor device according to a first embodiment;

FIG. 2A is a cross-sectional view taken along line A1-A1 in FIG. 1, illustrating an FET operation portion in the semiconductor device according to the first embodiment;

FIG. 2B is a cross-sectional view taken along line B1-B1 in FIG. 1, illustrating a non-FET operation portion in the semiconductor device according to the first embodiment;

FIG. 2C is a schematic enlarged view of the periphery of a high-concentration region in FIG. 2A;

FIG. 2D is a schematic enlarged view of the periphery of a high-concentration region in FIG. 2B;

FIG. 3 is a cross-sectional view common to the FET operation portion and the non-FET operation portion, for explaining an example of a manufacturing process of the semiconductor device according to the first embodiment;

FIG. 4A is a cross-sectional view of the FET operation portion, for explaining an example of a manufacturing process of the semiconductor device according to the first embodiment, following FIG. 3;

FIG. 4B is a cross-sectional view of the non-FET operation portion, for explaining an example of a manufacturing process of the semiconductor device according to the first embodiment, following FIG. 3;

FIG. 5A is a cross-sectional view of the FET operation portion, for explaining an example of a manufacturing process of the semiconductor device according to the first embodiment, following FIG. 4A;

FIG. 5B is a cross-sectional view of the non-FET operation portion, for explaining an example of a manufacturing process of the semiconductor device according to the first embodiment, following FIG. 4B;

FIG. 6A is a cross-sectional view of the FET operation portion, for explaining an example of a manufacturing process of the semiconductor device according to the first embodiment, following FIG. 5A;

FIG. 6B is a cross-sectional view of the non-FET operation portion, for explaining an example of a manufacturing process of the semiconductor device according to the first embodiment, following FIG. 5B;

FIG. 7A is a cross-sectional view of the FET operation portion, for explaining an example of a manufacturing process of the semiconductor device according to the first embodiment, following FIG. 6A;

FIG. 7B is a cross-sectional view of the non-FET operation portion, for explaining an example of a manufacturing process of the semiconductor device according to the first embodiment, following FIG. 6B;

FIG. 8 is a plan view of a semiconductor device according to a modification of the first embodiment;

FIG. 9A is a cross-sectional view taken along line A2-A2 in FIG. 8, illustrating an FET operation portion in the semiconductor device according to the modification of the first embodiment;

FIG. 9B is a cross-sectional view taken along line B2-B2 in FIG. 8, illustrating a non-FET operation portion in the semiconductor device according to the modification of the first embodiment;

FIG. 10 is a plan view of a semiconductor device according to a second embodiment;

FIG. 11A is a cross-sectional view taken along line A3-A3 in FIG. 10, and is a cross-sectional view of an FET operation portion in the semiconductor device according to the second embodiment;

FIG. 11B is a cross-sectional view taken along line B3-B3 in FIG. 10, and is a cross-sectional view of a non-FET operation portion in the semiconductor device according to the second embodiment;

FIG. 12A is a cross-sectional view of the FET operation portion, for explaining an example of a manufacturing process of the semiconductor device according to the second embodiment;

FIG. 12B is a cross-sectional view of the non-FET operation portion, for explaining an example of a manufacturing process of the semiconductor device according to the second embodiment;

FIG. 13 is a plan view of an interlayer insulating film in a manufacturing process of the semiconductor device according to the second embodiment; and

FIG. 14 is a plan view illustrating a distribution of the FET operation portions and the non-FET operation portions in the semiconductor device according to the embodiment.

### DETAILED DESCRIPTION

A semiconductor device according to an embodiment includes: a semiconductor layer including a first main surface and a second main surface; a first electrode provided on the first main surface; a second electrode provided on the second main surface via an interlayer insulating film; a first semiconductor region of a first conductivity type provided in the semiconductor layer and located on the first electrode; a second semiconductor region of a second conductivity type provided in the semiconductor layer and located on the first semiconductor region; and a third semiconductor region of the first conductivity type provided in the semiconductor layer and located between the second semiconductor region and the second electrode. The semiconductor layer includes a first portion and a second portion that are provided along a second direction orthogonal to a first direction heading from the first electrode to the second electrode. The first portion includes a third electrode provided in the second semiconductor region via an insulating region, and a fourth semiconductor region of the second conductivity type that is provided in the second semiconductor region, is electrically connected to the second electrode via a first contact part, and has an impurity concentration higher than an impurity concentration of the second semiconductor region. The second portion includes a conductive connection part provided in the second semiconductor region via an insulating region and electrically connected to the third electrode, and a fifth semiconductor region of the second conductivity type that is provided in the second semiconductor region, is electrically connected to the second electrode via a second contact part, and has an impurity concentration higher than the impurity concentration of the second semiconductor region. The length, in a third direction orthogonal to the first direction and the second direction, of the conductive connection part is smaller than the length, in the third direction, of the third electrode. The length, in the third direction, of the fifth semiconductor region is larger than the length, in the third direction, of the fourth semiconductor region.

Hereinafter, embodiments according to the present invention will be described with reference to the drawings. The embodiments are not intended to limit the present invention. The drawings are schematic or conceptual, and the ratio of each portion and the like are not necessarily the same as actual ones. In the specification and the drawings, the same elements as those described above with reference to the previously described drawings are denoted by the same reference numerals, and detailed description thereof is appropriately omitted.

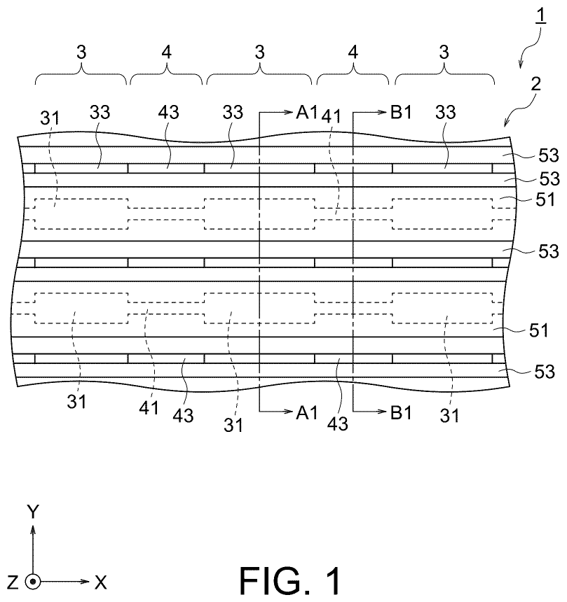

For convenience of description, an XYZ orthogonal coordinate system is adopted as illustrated in FIGS. 1 to 3 and the like. A Z-axis direction is the stacking direction (thickness direction) of a semiconductor device. In the Z-axis direction, the source electrode side is also referred to as “upper”, and the drain electrode side is also referred to as “lower”. However, this expression is for convenience and is unrelated to the direction of gravity. The Z-axis direction is a first direction in the claims. An X-axis direction is a second direction in the claims. A Y-axis direction is a third direction in the claims.

In the following description, notations of n⁺, n, n⁻, and p⁺, p, and p⁻ may be used to represent the relative level of impurity concentration in each conductivity type. That is, n⁺ indicates that the n-type impurity concentration is relatively higher than n, and n⁻ indicates that the n-type impurity concentration is relatively lower than n. In addition, p⁺ indicates that the p-type impurity concentration is relatively higher than p, and p⁻ indicates that the p-type impurity concentration is relatively lower than p. When both p-type impurities and n-type impurities are contained in each region, these notations represent the relative level of the net impurity concentration after the impurities have been compensated for. The n-type, n⁺-type, and n⁻-type are examples of a first conductivity type in the claims. The p-type, p⁺-type, and p⁻-type are examples of a second conductivity type in the claims. In the following description, the n-type and the p-type may be reversed. That is, the first conductivity type may be the p-type.

The impurity concentration of a semiconductor region can be measured by, for example, secondary ion mass spectrometry (SIMS). The relative level of the impurity concentration can also be determined from the level of a carrier concentration obtained by, for example, scanning capacitance microscopy (SCM).

In addition, dimensions, such as the width of a contact part, can be measured by analysis of a surface or a cross section by, for example, transmission electron microscope (TEM), energy dispersive X-ray spectroscopy (EDX), or scanning electron microscope (SEM), or the like.

Note that, for example, terms such as “identical” and “same”, dimensions, values of physical properties, and the like, which specify shapes, geometric conditions, physical properties, and degrees thereof, used in the present specification, are to be interpreted to include a range that allows for similar functions, without being bound by strict meanings.

### First Embodiment

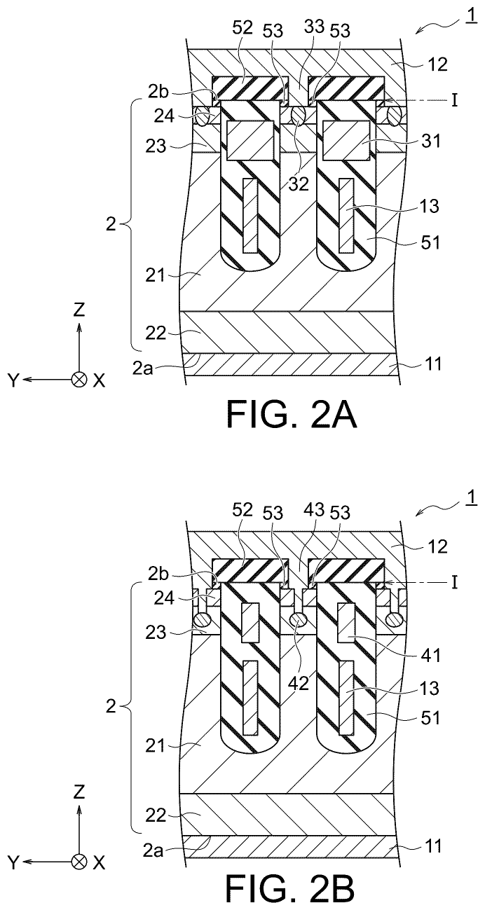

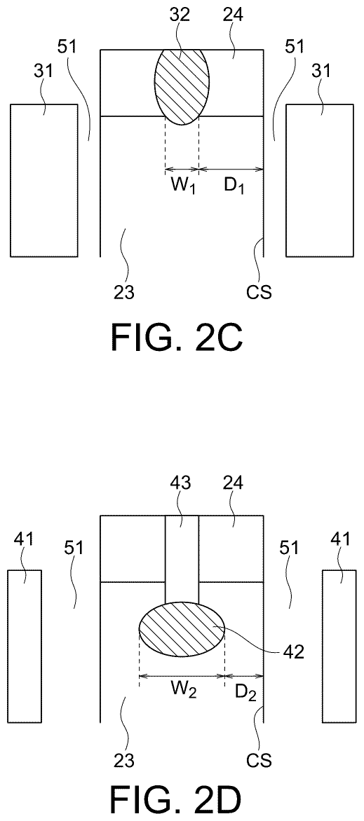

A semiconductor device 1 according to a first embodiment will be described with reference to FIG. 1 and FIGS. 2A to 2D. FIG. 1 is a plan view of the semiconductor device 1 according to the present embodiment, and illustrates a plan view at a position I in FIGS. 2A and 2B. FIG. 2A is a cross-sectional view taken along line A1-A1 in FIG. 1, and FIG. 2B is a cross-sectional view taken along line B1-B1 in FIG. 1. FIG. 2C is a schematic enlarged view of the periphery of a high-concentration region 32 in FIG. 2A. FIG. 2D is a schematic enlarged view of the periphery of a high-concentration region 42 in FIG. 2B. The semiconductor device 1 is a vertical MOSFET.

As illustrated in FIG. 1, the semiconductor device 1 includes a semiconductor layer 2 having an FET operation portion 3 and a non-FET operation portion 4 that are provided along the X-axis direction. The FET operation portion 3 is an example of a first portion in the claims. The non-FET operation portion 4 is an example of a second portion in the claims.

In the present embodiment, the FET operation portions 3 and the non-FET operation portions 4 are alternately provided along the X-axis direction. That is, the semiconductor layer 2 includes a plurality of sets of the FET operation portions 3 and the non-FET operation portions 4 along the X-axis direction.

When a voltage is applied to a gate electrode (a gate electrode 31 to be described later) of the semiconductor device 1, a channel is formed in a base region of the FET operation portion 3, leading to an FET operation. On the other hand, a channel is not formed in a base region of the non-FET operation portion 4, leading to no FET operation. The FET operation portion 3 and the non-FET operation portion 4 will be described in detail later.

FIG. 2A is a view illustrating a part of the cross section taken along line A1-A1 in FIG. 1, that is, a cross-sectional view of the FET operation portion 3. FIG. 2B is a view illustrating a part of the cross section taken along line B1-B1 in FIG. 1, that is, a cross-sectional view of the non-FET operation portion 4.

As illustrated in FIGS. 2A and 2B, the semiconductor device 1 includes the semiconductor layer 2 including a lower surface (first main surface) 2a and an upper surface (second main surface) 2b opposite to the lower surface 2a, a drain electrode 11 provided on the lower surface 2a of the semiconductor layer 2, and a source electrode 12 provided on the upper surface 2b of the semiconductor layer 2 via an interlayer insulating film 52. Note that the interlayer insulating film 52 is, for example, a silicon oxide film.

The semiconductor layer 2 may be an epitaxial layer, a semiconductor substrate, or a semiconductor substrate and an epitaxial layer disposed on the semiconductor substrate. In the present embodiment, the semiconductor layer 2 is silicon (Si). In this case, for example, arsenic (As), phosphorus (P), or antimony (Sb) is used as the n-type impurity, and for example, boron (B) is used as the p-type impurity. Note that the semiconductor layer 2 may be made of a compound semiconductor such as silicon carbide (SiC) or gallium nitride (GaN).

The drain electrode 11 functions as the drain electrode of the MOSFET. The drain electrode 11 is made of, for example, copper (Cu), titanium (Ti), tungsten (W), aluminum (A1), or the like. The drain electrode 11 is an example of a first electrode in the claims.

The source electrode 12 functions as the source electrode of the MOSFET. As described later, the source electrode 12 is electrically connected to the semiconductor layer 2 via a contact part 33 and a contact part 43. The source electrode 12 is made of, for example, copper (Cu), titanium (Ti), tungsten (W), aluminum (A1), or the like. The source electrode 12 is an example of a second electrode in the claims.

Next, for the details of the semiconductor layer 2, a configuration common to the FET operation portion 3 and the non-FET operation portion 4 will be described, and thereafter, configurations different from each other between the FET operation portion 3 and the non-FET operation portion 4 will be described.

As illustrated in FIGS. 2A and 2B, the FET operation portion 3 and the non-FET operation portion 4 of the semiconductor layer 2 are provided with a drift region 21, a drain region 22, a base region 23, a source region 24, an insulating region (gate insulating film) 51, and an interlayer insulating film 53.

The drift region 21 functions as the drift region of the MOSFET. The drift region 21 is disposed on the drain region 22 (above the drain electrode 11). The drift region 21 is, for example, an n⁻-type semiconductor region. The n-type impurity concentration of the drift region 21 is, for example, between 1×10¹⁵ cm⁻³ and 2×10¹⁶ cm⁻³ (inclusive).

The drain region 22 functions as the drain region of the MOSFET. The drain region 22 is disposed between the drift region 21 and the drain electrode 11. The drain region 22 is, for example, an n⁺-type semiconductor region. The n-type impurity concentration of the drain region 22 is, for example, between 1×10¹⁸ cm⁻³ and 1×10²¹ cm⁻³ (inclusive).

Each of the drift region 21 and the drain region 22 is an example of a first semiconductor region in the claims. Note that the first semiconductor region in the claims may include both the drift region 21 and the drain region 22, or may include only one of the drift region 21 and the drain region 22.

The base region 23 functions as the base region of the MOSFET. The base region 23 is disposed on the drift region 21 as viewed in the up-down direction (Z-axis direction) of the semiconductor device 1, and is disposed to be sandwiched between the insulating regions 51 as viewed in the left-right direction (Y-axis direction). The base region 23 is, for example, a p-type semiconductor region. The p-type impurity concentration of the base region 23 is, for example, between 1×10¹⁶ cm⁻³ and 1×10²⁰ cm⁻³ (inclusive). The base region 23 is an example of a second semiconductor region in the claims.

The source region 24 functions as the source region of the MOSFET. The source region 24 is located between the base region 23 and the source electrode 12 as viewed in the up-down direction (Z-axis direction) of the semiconductor device 1. In the present embodiment, the source region 24 is located between the base region 23 and the interlayer insulating film 53. Note that the semiconductor layer 2 may not include the interlayer insulating film 53. In this case, the upper end of the source region 24 is located on the upper surface 2b of the semiconductor layer 2. The source region 24 is, for example, an n⁺-type semiconductor region. The n-type impurity concentration of the source region 24 is, for example, between 1×10¹⁸ cm⁻³ and 1×10²² cm⁻³ (inclusive). The source region 24 is an example of a third semiconductor region in the claims.

The insulating region 51 is provided to reach the drift region 21 from the upper surface 2b of the semiconductor layer 2. The insulating region 51 is made of a dielectric, such as silicon oxide or silicon nitride, which covers the inner wall of a gate trench provided to reach the drift region 21 from the upper surface 2b of the semiconductor layer 2.

Note that the semiconductor device 1 may further include a field plate electrode (FP electrode) 13 provided in the semiconductor layer 2 via the insulating region 51. In the present embodiment, the FP electrode 13 is provided below the gate electrode 31 and a conductive connection part 41 to extend in the X-axis direction. The FP electrode 13 is made of, for example, polysilicon containing p-type or n-type impurities, or the like. The FP electrode 13 is electrically insulated from semiconductor layer 2 by the insulating region 51, and is electrically connected to the source electrode 12. By providing such an FP electrode 13, a depletion layer extends from the FP electrode 13 to the drift region 21 around the FP electrode 13 by the voltage applied between the drain electrode 11 and the source electrode 12, when the MOSFET is in an off state. When this depletion layer is connected to the depletion layer of the adjacent FP electrode 13, the breakdown voltage of the semiconductor device 1 can be improved. Note that the FP electrode 13 may be provided in the semiconductor layer 2 via an insulating region different from the insulating region 51. In addition, the FP electrode 13 may be provided to extend in a direction other than the X-axis direction (e.g., the Y-axis direction).

Next, configurations of the FET operation portion 3 and the non-FET operation portion 4 in the semiconductor layer 2, which are different from each other, will be described.

As illustrated in FIG. 2A, the FET operation portion 3 of the semiconductor layer 2 further includes the gate electrode 31 and the high-concentration region 32. In addition, the contact part 33 is provided in the FET operation portion 3 of the semiconductor layer 2. The contact part 33 electrically connects the source electrode 12 to the source region 24 and the high-concentration region 32. The contact part 33 penetrates the interlayer insulating films 52 and 53 but does not penetrate the source region 24. That is, the upper end of the contact part 33 is connected to the source electrode 12, and the lower end of the contact part 33 is located at the same height as that of the upper end of the source region 24. That is, the contact part 33 is in contact with the source region 24 at the lower end.

The gate electrode 31 of the FET operation portion 3 functions as the gate electrode of the MOSFET. The gate electrode 31 is provided in the base region 23 via the insulating region 51 and extends in the X-axis direction. The gate electrode 31 is made of, for example, polysilicon containing p-type or n-type impurities, or the like. When a voltage is applied to the gate electrode 31, a channel (inversion layer) is formed in the base region 23 near the interface (channel surface) between the base region 23 and the insulating region 51, causing carriers to flow between the drift region 21 and the source region 24. As described above, the semiconductor device 1 is configured to perform the FET operation in the FET operation portion 3. The gate electrode 31 is an example of a third electrode in the claims.

The high-concentration region 32 of the FET operation portion 3 is mainly provided in the source region 24, and a part of the lower end is provided in the base region 23. In other words, the high-concentration region 32 is provided in the base region 23 and further extends into the source region 24. In addition, the high-concentration region 32 is connected to the contact part 33 at the upper end, and is connected to the base region 23 at the lower end. The high-concentration region 32 is electrically connected to the source electrode 12 via the contact part 33. The high-concentration region 32 is, for example, a p⁺-type semiconductor region having an impurity concentration higher than that of the base region 23. The p-type impurity concentration of the high-concentration region 32 is, for example, between 1×10¹⁸ cm⁻³ and 1×10²¹ cm⁻³ (inclusive). The high-concentration region 32 is an example of a fourth semiconductor region in the claims. Since the high-concentration region 32 and the contact part 33 are provided, minority carriers accumulated in the base region 23 are injected into the high-concentration region 32, pass through the contact part 33, and are discharged to the source electrode 12.

In the present embodiment, a part of the lower end of the contact part 33 is in contact with the source region 24. In more detail, the length, in the Y-axis direction, of the lower end of the contact part 33 is larger than the length, in the Y-axis direction, of the upper end of the high-concentration region 32, and the excess portion of the lower end of the contact part 33 is in contact with the source region 24. As a result, the source electrode 12 and the source region 24 are electrically connected via the contact part 33 in the FET operation portion 3.

As illustrated in FIG. 2B, the non-FET operation portion 4 of the semiconductor layer 2 further includes the conductive connection part 41 and the high-concentration region 42. In addition, the non-FET operation portion 4 is provided with the contact part 43. The contact part 43 electrically connects the source electrode 12 to the source region 24 and the high-concentration region 42. The contact part 43 is provided to penetrate the interlayer insulating films 52 and 53 and further penetrate the source region 24. That is, the upper end of the contact part 43 is connected to the source electrode 12, and the lower end of the contact part 43 is located in the base region 23. In more detail, the lower end of the contact part 43 is located closer to the drain electrode 11 than the upper end of the base region 23 is, and is located closer to the source electrode 12 than the lower end of the base region 23 is. In addition, the contact part 43 is connected to the high-concentration region 42 at the lower end.

The conductive connection part 41 of the non-FET operation portion 4 is provided in the base region 23 via the insulating region 51 and extends in the X-axis direction. The conductive connection part 41 is made of, for example, polysilicon containing p-type or n-type impurities, or the like. The conductive connection part 41 is electrically connected to the gate electrode 31. In the present embodiment, the FET operation portions 3 and the non-FET operation portions 4 are alternately arranged along the X-axis direction, and thus the conductive connection part 41 electrically connects the two gate electrodes 31 adjacent in the X-axis direction.

As illustrated in FIGS. 2A and 2B, the width of the conductive connection part 41 of the non-FET operation portion 4 is smaller than the width of the gate electrode 31 of the FET operation portion 3. That is, the length, in the Y-axis direction, of the conductive connection part 41 is smaller than the length, in the Y-axis direction, of the gate electrode 31.

The high-concentration region 42 of the non-FET operation portion 4 is provided in the base region 23. The high-concentration region 42 is electrically connected to the source electrode 12 via the contact part 43. The high-concentration region 42 is, for example, a p⁺-type semiconductor region having an impurity concentration higher than that of the base region 23. The p-type impurity concentration of the high-concentration region 42 is, for example, between 1×10¹⁸ cm⁻³ and 1×10²¹ cm⁻³ (inclusive). The high-concentration region 42 is an example of a fifth semiconductor region in the claims.

Since the high-concentration region 42 and the contact part 43 are provided, minority carriers accumulated in the base region 23 are injected into the high-concentration region 42, pass through the contact part 43, and are discharged to the source electrode 12.

The width of the high-concentration region 42 is larger than the width of the high-concentration region 32 in the base region 23. That is, a length W2, in the Y-axis direction, of the high-concentration region 42 in the base region 23 is larger than a length W1, in the Y-axis direction, of the high-concentration region 32 in the base region 23, as illustrated in FIGS. 2C and 2D. Note that the high-concentration region 42 may be in contact with the insulating region 51.

As described above, the semiconductor device 1 according to the first embodiment includes the semiconductor layer 2 having the FET operation portion 3 and the non-FET operation portion 4 that are provided along the X-axis direction. The FET operation portion 3 includes: the gate electrode 31 provided in the base region 23 via the insulating region 51; and the high-concentration region 32 of the second conductivity type that is provided in the base region 23, is electrically connected to the source electrode 12 via the contact part 33, and has an impurity concentration higher than that of the base region 23. The non-FET operation portion 4 includes: the conductive connection part 41 provided in the base region 23 via the insulating region 51 and electrically connected to the gate electrode 31; and the high-concentration region 42 of the second conductivity type that is provided in the base region 23, is electrically connected to the source electrode 12 via the contact part 43, and has an impurity concentration higher than that of the base region 23. Here, the length, in the Y-axis direction, of the conductive connection part 41 is smaller than the length, in the Y-axis direction, of the gate electrode 31. In addition, the length, in the Y-axis direction, of the high-concentration region 42 in the base region 23 is larger than the length, in the Y-axis direction, of the high-concentration region 32 in the base region 23. That is, the length, in the Y-axis direction, of the high-concentration region 32 is smaller than the length, in the Y-axis direction, of the high-concentration region 42.

In the non-FET operation portion 4, the length, in the Y-axis direction, of the conductive connection part 41 is smaller than the length, in the Y-axis direction, of the gate electrode 31, as described above. Therefore, the conductive connection part 41 in the non-FET operation portion 4 is farther from the interface (channel surface) between the base region 23 and the insulating region 51 than the gate electrode 31 in the FET operation portion 3 is. Therefore, in the non-FET operation portion 4, channel formation in the base region 23 is suppressed, and the FET operation is suppressed. In the present embodiment, the high-concentration region 42 is wider than the high-concentration region 32, and thus in the non-FET operation portion 4, minority carriers accumulated in the base region 23 are easily injected into the high-concentration region 42. Therefore, the avalanche breakdown tolerance of the semiconductor device 1 can be improved.

On the other hand, in the FET operation portion 3, the length, in the Y-axis direction, of the high-concentration region 32 in the base region 23 is smaller than the length, in the Y-axis direction, of the high-concentration region 42. In more detail, the length W1, in the Y-axis direction, of the high-concentration region 32 in the base region 23 is smaller than the length W2, in the Y-axis direction, of the high-concentration region 42 in the base region 23, as illustrated in FIGS. 2C and 2D. Therefore, the high-concentration region 32 is farther from the boundary (channel surface) between the base region 23 and the insulating region 51 than the high-concentration region 42 is. In more detail, a distance D1, in the Y-axis direction, between the high-concentration region 32 and the channel surface is larger than a distance D2, in the Y axis direction, between the high-concentration region 42 and the channel surface. As a result, even if misalignment or the like of an opening, in which the contact part 33 is provided, occurs in the manufacturing process of the semiconductor device 1, the high-concentration region 32 is suppressed from being closer to the channel surface. Therefore, a fluctuation in the threshold voltage of the semiconductor device 1 can be suppressed.

Therefore, according to the first embodiment, it is possible to provide the semiconductor device 1 capable of improving its avalanche breakdown tolerance while suppressing a fluctuation in the threshold voltage.

Note that the impurity concentration of the high-concentration region 42 may be higher than the impurity concentration of the high-concentration region 32. Here, the impurity concentration of the high-concentration region 42 is the highest impurity concentration in the high-concentration region 42. Similarly, the impurity concentration of the high-concentration region 32 is the highest impurity concentration in the high-concentration region 32. As a result, minority carriers accumulated in the base region 23 are easily injected into the high-concentration region 42, whereby the avalanche breakdown tolerance of the semiconductor device 1 can be further improved.

In the example of FIG. 2A, the contact part 33 is in contact with the source region 24 at the lower end, but the contact part 33 may be provided up to the middle of the source region 24. That is, the lower end of the contact part 33 may be located between the upper end and the lower end of the source region 24. Even in this case, the high-concentration region 32 is provided to be connected to the lower end of the contact part 33 and the base region 23.

### <Method of Manufacturing Semiconductor Device 1>

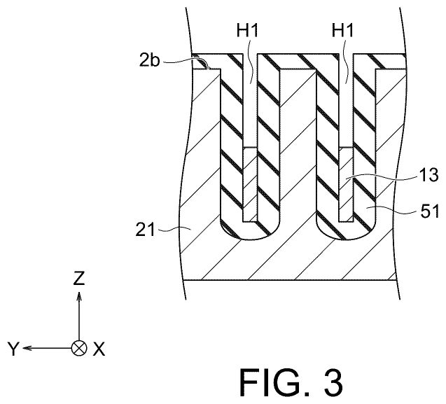

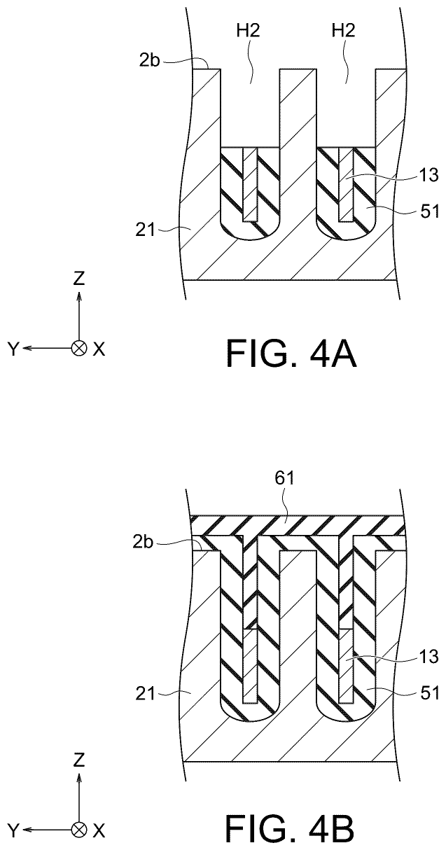

Next, an example of a method of manufacturing the semiconductor device 1 according to the present embodiment will be described with reference to FIGS. 3 to 7B. FIG. 3 is a cross-sectional view common to the FET operation portion 3 and the non-FET operation portion 4, for explaining an example of a manufacturing process of the semiconductor device 1 according to the first embodiment. FIGS. 4A, 5A, 6A, and 7A are cross-sectional views of the FET operation portion 3 for explaining an example of the manufacturing process of the semiconductor device 1 according to the first embodiment. FIGS. 4B, 5B, 6B, and 7B are cross-sectional views of the non-FET operation portion 4 for explaining an example of the manufacturing process of the semiconductor device 1 according to the first embodiment.

First, a semiconductor layer, including the drift region 21, the insulating region 51 extending from the upper surface 2b into the drift region 21, and the FP electrode 13 provided in the insulating region 51, is prepared, as illustrated in FIG. 3.

The semiconductor layer illustrated in FIG. 3 is obtained, for example, as follows. First, a semiconductor layer including the drift region 21 is prepared. The semiconductor layer is, for example, an n-type semiconductor substrate. Thereafter, a gate trench is formed in the upper surface 2b of the semiconductor layer by reactive ion etching (RIE) or the like. Thereafter, the insulating region 51, which covers the inner wall of the gate trench and the upper surface 2b, is formed by thermal oxidation or the like. Thereafter, a part of the insulating region 51 formed in the gate trench is removed by RIE or the like. Thereafter, a conductive material, such as polysilicon, is deposited by chemical vapor deposition (CVD) or the like, and the excess conductive material is etched back to form the FP electrodes 13. An opening H1 is formed above the FP electrode 13.

Next, a resist 61 is formed in the non-FET operation portion 4 by photolithography or the like, as illustrated in FIGS. 4A and 4B. The resist 61 fills the opening H1 and covers the insulating region 51 in the non-FET operation portion 4. The resist 61 is not formed in the FET operation portion 3. Thereafter, an upper portion (a portion above the FP electrode 13) of the insulating region 51 in the FET operation portion 3 is removed by wet etching or the like, as illustrated in FIG. 4A. As a result, an opening H2 wider than the opening H1 is formed in the FET operation portion 3. On the other hand, the insulating region 51 of the non-FET operation portion 4 is maintained as it is.

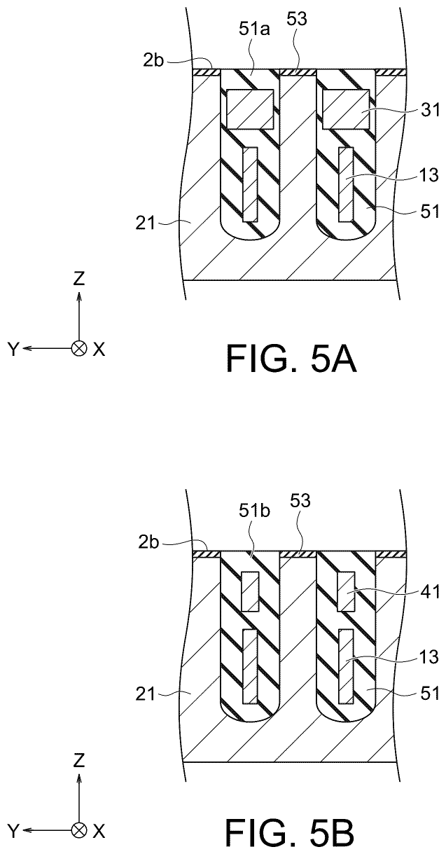

Next, the resist 61 of the non-FET operation portion 4 is removed as illustrated in FIGS. 5A and 5B. As a result, the opening H1 is exposed in the non-FET operation portion 4. Thereafter, an upper portion (a portion above the upper surface 2b) of the insulating region 51 in the non-FET operation portion 4 is removed by chemical mechanical polishing (CMP) or the like. Thereafter, a silicon oxide film is grown in the opening H2 of the FET operation portion 3 and the opening H1 of the non-FET operation portion 4 by thermal oxidation or the like. Thereafter, a conductive material, such as polysilicon, is deposited in the openings H1 and H2 by CVD or the like, and the excess conductive material is etched back. As a result, the gate electrode 31 is formed in the opening H2 of the FET operation portion 3, and the conductive connection part 41 is formed in the opening H1 of the non-FET operation portion 4. Thereafter, an insulating region 51a that covers the gate electrode 31, an insulating region 51b that covers the conductive connection part 41, and the interlayer insulating film 53 that covers a portion, exposed to the upper surface 2b, of the semiconductor layer 2, are formed by thermal oxidation or the like. Note that the following description will be made by assuming that the insulating region 51a and the insulating region 51b are a part of the insulating region 51, and the upper surface of the interlayer insulating film 53 is the upper surface 2b of the semiconductor layer.

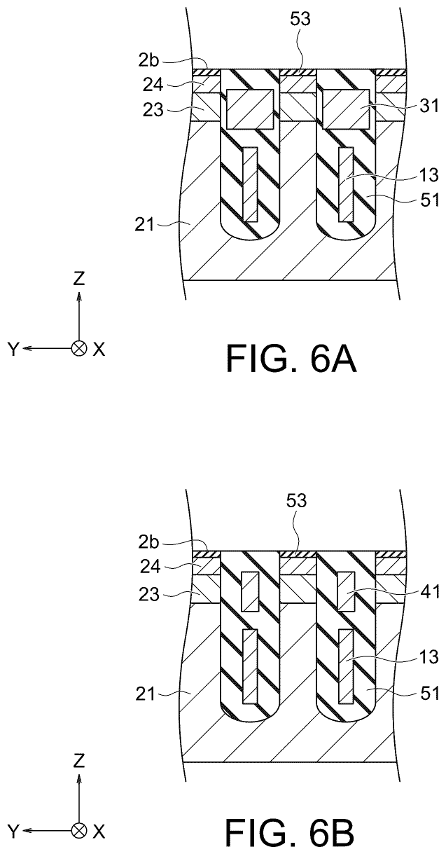

Next, p-type impurities are ion implanted into the upper surface 2b of the semiconductor layer to form the base region 23, as illustrated in FIGS. 6A and 6B. Thereafter, n-type impurities are ion implanted into the upper surface 2b of the semiconductor layer to form the source region 24.

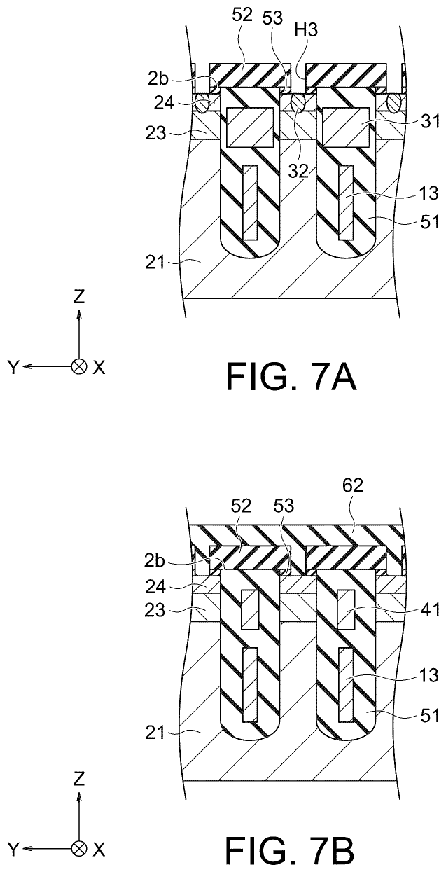

Next, the interlayer insulating film 52 is formed on the upper surface 2b of the semiconductor layer by CVD or the like, as illustrated in FIGS. 7A and 7B. Thereafter, an opening H3 is formed in the interlayer insulating films 52 and 53 in each of the regions of the FET operation portion 3 and the non-FET operation portion 4 by RIE or the like. The opening H3 penetrates the interlayer insulating films 52 and 53, and the source region 24 is exposed at the bottom surface of the opening H3. The opening H3 in the FET operation portion 3 is a trench in which the contact part 33 will be provided in a later process. Thereafter, a resist 62 for covering the opening H3 in the non-FET operation portion 4 is formed by photolithography or the like. The resist 62 does not cover the opening H3 in the FET operation portion 3. Thereafter, p-type impurities are ion implanted into the upper surface 2b of the semiconductor layer to form the high-concentration region 32 in the FET operation portion 3. Note that the ion implantation is performed such that at least the high-concentration region 32 is connected to the base region 23.

Thereafter, the resist 62 of the non-FET operation portion 4 is removed. Thereafter, a resist, which covers the FET operation portion 3 and does not cover the non-FET operation portion 4, is formed by photolithography or the like, and a trench (lower trench), which penetrates the source region 24 from the bottom surface of the opening H3 and reaches the base region 23 in the non-FET operation portion 4, is formed by RIE or the like. The lower trench is a trench in which a lower portion of the contact part 43 will be provided in a later process. Thereafter, the resist covering the FET operation portion 3 is removed.

Thereafter, the opening H3 of the non-FET operation portion 4 and the opening H3 of the FET operation portion 3 are expanded in the Y-axis direction by wet etching or the like. As a result, when the contact part 33 is formed in the FET operation portion 3 in a later process, the lower end of the contact part 33 can be made to be firmly in contact with the source region 24. In addition, the opening H3 (upper trench) in the non-FET operation portion 4 after the expansion is a trench in which the upper portion of the contact part 43 will be provided in a later process.

Thereafter, a resist, which covers the FET operation portion 3 and does not cover the non-FET operation portion 4, is formed by photolithography or the like. Thereafter, p-type impurities are ion implanted into the upper surface 2b of the semiconductor layer to form the high-concentration region 42 in the non-FET operation portion 4. Thereafter, the resist covering the FET operation portion 3 is removed.

Thereafter, an activation process is performed. That is, a heat treatment is performed by rapid thermal anneal (RTA) or the like, so that the ions implanted into the base region 23, the source region 24, the high-concentration region 32, and the high-concentration region 42 are activated. Note that the activation process may be performed after each ion implantations is performed.

Thereafter, a conductive material is deposited in the trench by CVD, physical vapor deposition (PVD), or the like to form the contact part 33 and the contact part 43. The conductive material is, for example, a metal material containing copper, titanium, tungsten, aluminum, or the like, or the like. Note that the openings and the inside of the trench may be cleaned before depositing the conductive material. Thereafter, the source electrode 12 is formed on the upper surface 2b of the semiconductor layer 2. The source electrode 12 may be formed continuously after the contact part 33 and the contact part 43 are formed.

Thereafter, n-type impurities are ion implanted into the lower surface 2a of the semiconductor layer 2 and a heat treatment is performed, so that the drain region 22 is formed. Thereafter, the drain electrode 11 is formed to cover the lower surface 2a of the semiconductor layer 2.

Through the above processes, the semiconductor device 1 according to the first embodiment is manufactured. According to the manufacturing method of the present embodiment, even if the position of the high-concentration region 32 is shifted in the Y-axis direction due to a shift, in the Y-axis direction, of the position of the opening H3 for forming the contact part 33, a fluctuation in the threshold voltage of the semiconductor device 1 can be suppressed because the width (length in the Y-axis direction) of the high-concentration region 32 in the base region 23 is small. Similarly, even if the position of the high-concentration region 42 is shifted in the Y-axis direction due to a shift, in the Y-axis direction, of the position of the lower trench for forming the contact part 43, a fluctuation in the threshold voltage of the semiconductor device 1 can be suppressed because the FET operation is suppressed in the non-FET operation portion 4.

Note that, in the manufacturing process of the semiconductor device 1, not only the case where the position of at least one of the opening H3 and the lower trench is shifted in the Y-axis direction, but also the case where the width (length in the Y-axis direction) of at least one of the opening H3 and the lower trench varies, may occur. According to the manufacturing method of the present embodiment, a fluctuation in the threshold voltage of the semiconductor device 1 can be suppressed even if the width of at least one of the opening H3 and the lower trench varies.

Next, a modification according to the first embodiment will be described focusing on differences from the first embodiment.

### (Modification of First Embodiment)

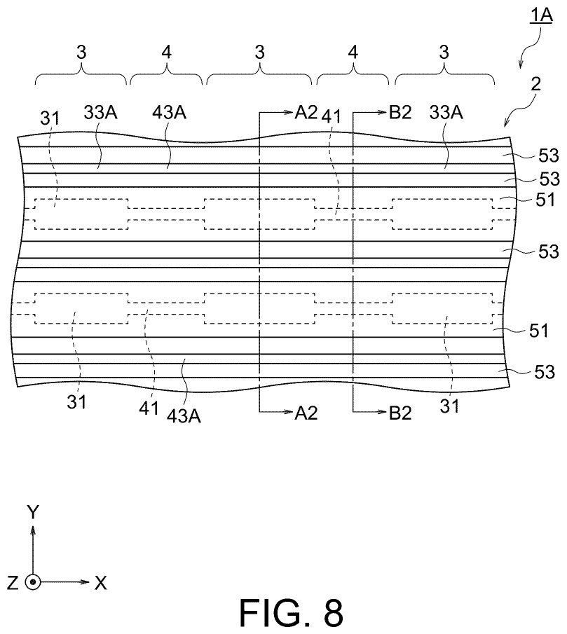

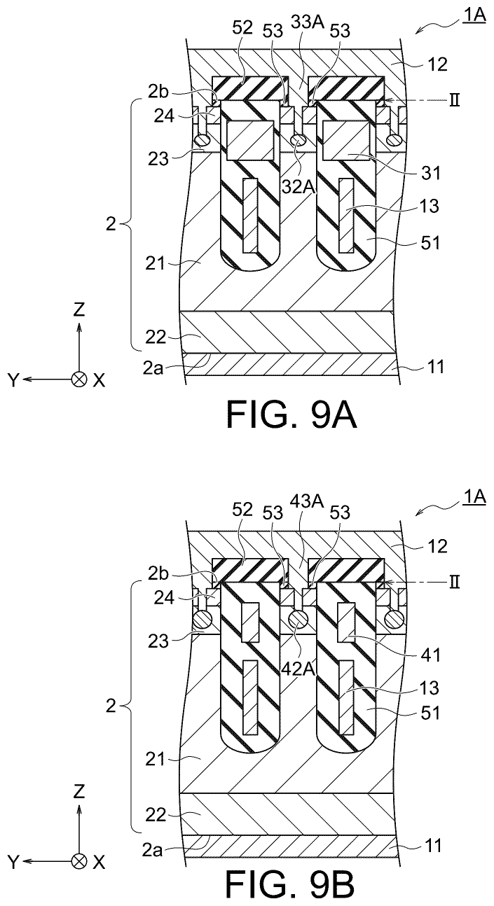

A semiconductor device 1A according to a modification of the first embodiment will be described with reference to FIGS. 8, 9A, and 9B. FIG. 8 is a plan view of the semiconductor device 1A according to the present modification, and illustrates a plan view at a position II in FIGS. 9A and 9B. FIG. 9A is a view illustrating a part of a cross section taken along line A2-A2 in FIG. 8, that is, a cross-sectional view of the FET operation portion 3. FIG. 9B is a view illustrating a part of a cross section taken along line B2-B2 in FIG. 8, that is, a cross-sectional view of the non-FET operation portion 4.

In the first embodiment described above, the high-concentration region 32 is mainly provided in the source region 24, and only the tip portion is provided in the base region 23. On the other hand, in the present modification, a high-concentration region 32A is entirely provided in the base region 23.

In the present modification, a contact part 33A is provided at a position where the upper end is connected to the source electrode 12, the lower end is closer to the drain electrode 11 (lower side) than the upper end of the base region 23 is, and the lower end is closer to the source electrode 12 (upper side) than the lower end of the base region 23 is, as illustrated in FIG. 9A.

Also in the present modification, the width (length in the Y-axis direction) of a high-concentration region 42A in the base region 23 is larger than the width of the high-concentration region 32A, as illustrated in FIGS. 9A and 9B. In other words, the width of the high-concentration region 32A in the base region 23 is smaller than the width of the high-concentration region 42A in the base region 23.

Therefore, also in the present modification, the high-concentration region 32A in the FET operation portion 3 is farther from the boundary (channel surface) between the base region 23 and the insulating region 51 than the high-concentration region 42A in the non-FET operation portion 4 is. In addition, the width of the high-concentration region 42A in the base region 23 is larger than the width of the high-concentration region 32A. This makes it possible to improve the avalanche breakdown tolerance while suppressing a fluctuation in the threshold voltage.

Note that, in the example illustrated in FIG. 9A, the width (length in the Y-axis direction) of a portion, penetrating the interlayer insulating films 52 and 53, of the contact part 33A is larger than the width of a portion penetrating the base region 23 and the source region 24, similarly to the first embodiment. However, the present modification is not limited thereto, and the width of the portion, penetrating the interlayer insulating films 52 and 53, of the contact part 33A may be the same as the width of the portion penetrating the base region 23 and the source region 24.

### <Method of Manufacturing Semiconductor Device 1A>

An example of a method of manufacturing the semiconductor device 1A according to the modification of the first embodiment will be described.

First, of the manufacturing process of the semiconductor device 1 according to the first embodiment, the processes up to the process of forming the opening H3 in the interlayer insulating films 52 and 53 are performed.

Thereafter, in each of the regions of the FET operation portion 3 and the non-FET operation portion 4, a trench, which penetrates the source region 24 to reach the base region 23, is formed by removing the source region 24 at the bottom of the opening H3 and a part of the base region 23 thereunder by RIE or the like. The trench is a trench in which either the contact part 33A or the contact part 43A is provided in a later process.

Thereafter, parts of the interlayer insulating films 52 and 53 are removed by wet etching or the like, whereby the opening H3 of each of the FET operation portion 3 and the non-FET operation portion 4 is expanded in the Y-axis direction. As a result, in the contact part 33A and the contact part 43A that are to be formed later, the width (length in the Y-axis direction) of the portion penetrating the interlayer insulating films 52 and 53 is larger than the width of the portion penetrating the source region 24. Note that this process may be omitted. In this case, in the contact part 33A and the contact part 43A, the width of the portion penetrating the interlayer insulating films 52 and 53 is the same as the width of the portion penetrating the base region 23 and the source region 24.

Thereafter, a resist, which covers the non-FET operation portion 4 and does not cover the FET operation portion 3, is formed by photolithography or the like. Thereafter, p-type impurities are ion implanted into the upper surface 2b of the semiconductor layer to form the high-concentration region 32A in the FET operation portion 3. Thereafter, the resist covering the non-FET operation portion 4 is removed.

Thereafter, a resist, which covers the FET operation portion 3 and does not cover the non-FET operation portion 4, is formed by photolithography or the like. Thereafter, p-type impurities are ion implanted into the upper surface 2b of the semiconductor layer to form the high-concentration region 42A in the non-FET operation portion 4. The ion implantation in this process is performed by oblique ion implantation or the like such that the width of the high-concentration region 42A is larger than the width of the high-concentration region 32A. Thereafter, the resist covering the FET operation portion 3 is removed.

Thereafter, an activation process is performed. The subsequent processes are similar to the manufacturing process of the semiconductor device 1.

Through the above processes, the semiconductor device 1A according to the modification of the first embodiment is manufactured.

### Second Embodiment

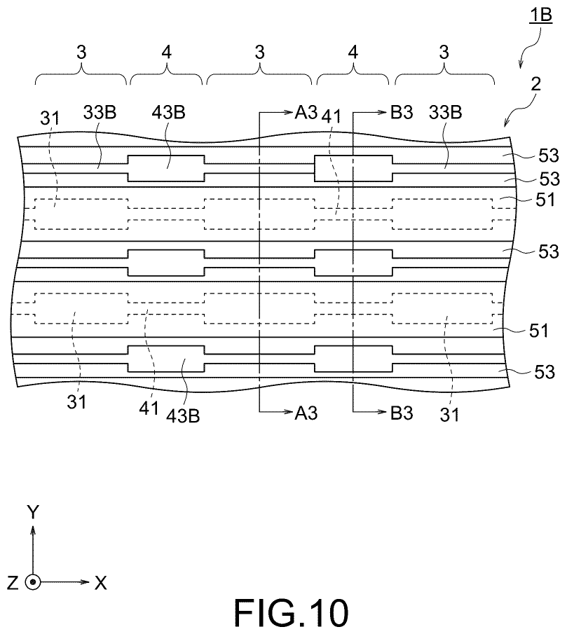

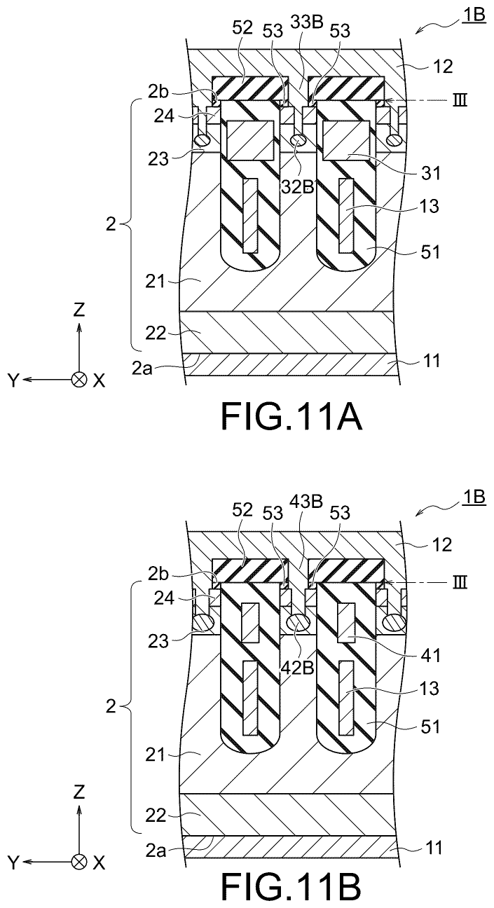

A semiconductor device 1B according to a second embodiment will be described with reference to FIGS. 10, 11A, and 11B. FIG. 10 is a plan view of the semiconductor device 1B according to the present embodiment, and illustrates a plan view at a position III in FIGS. 11A and 11B. FIG. 11A is a view illustrating a part of a cross section taken along line A3-A3 in FIG. 10, that is, a cross-sectional view of the FET operation portion 3. FIG. 11B is a view illustrating a part of a cross section taken along line B3-B3 in FIG. 10, that is, a cross-sectional view of the non-FET operation portion 4.

In the modification of the first embodiment described above, the width of the contact part 33A in the source region 24 is the same as the width of the contact part 43A. On the other hand, in the second embodiment, the width of a contact part 43B in the source region 24 is larger than the width of a contact part 33B in the source region 24. Hereinafter, the semiconductor device 1B according to the present embodiment will be described focusing on differences from the modification of the first embodiment.

In the FET operation portion 3 in the semiconductor device 1B, the contact part 33B is provided to penetrate the source region 24 to reach the middle of the base region 23, as illustrated in FIG. 11A. That is, the contact part 33B is provided at a position where the upper end is connected to the source electrode 12, the lower end is closer to the drain electrode 11 than the upper end of the base region 23 is, and the lower end is closer to the source electrode 12 than the lower end of the base region 23 is. In addition, a high-concentration region 32B is provided to be connected to the lower end of the contact part 33B.

In the base region 23 and the source region 24, the width of the contact part 43B is larger than the width of the contact part 33B, as illustrated in FIGS. 11A and 11B. That is, the length, in the Y-axis direction, of the contact part 43B in the base region 23 and the source region 24 is larger than the length, in the Y-axis direction, of the contact part 33B in the base region 23 and the source region 24.

Also in the present embodiment, the width (length in the Y-axis direction) of the high-concentration region 42B in the base region 23 is larger than the width of the high-concentration region 32B. In other words, the width of the high-concentration region 32B in the base region 23 is smaller than the width of the high-concentration region 42B in the base region 23.

Therefore, also in the present embodiment, the avalanche breakdown tolerance can be improved while suppressing a fluctuation in the threshold voltage.

### <Method of Manufacturing Semiconductor Device 1B>

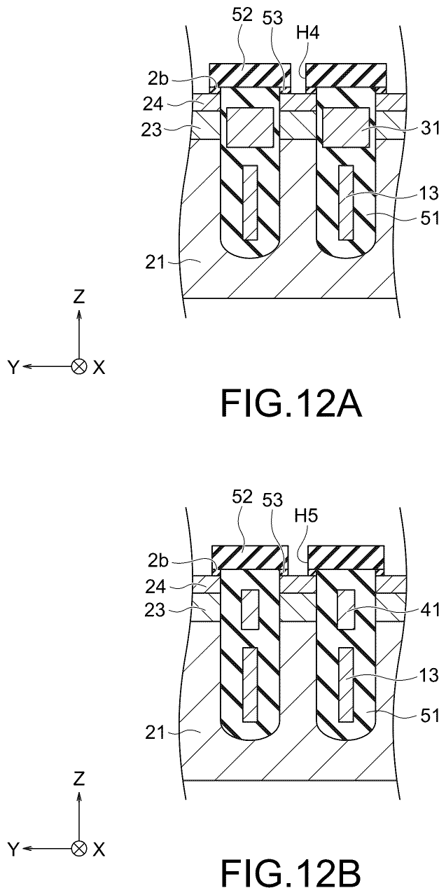

Next, an example of a method of manufacturing the semiconductor device 1B according to the second embodiment will be described with reference to FIGS. 12A and 12B. FIG. 12A is a cross-sectional view of the FET operation portion 3, for explaining an example of a manufacturing process of the semiconductor device according to the second embodiment. FIG. 12B is a cross-sectional view of the non-FET operation portion 4, for explaining an example of a manufacturing process of the semiconductor device according to the second embodiment.

First, of the manufacturing process of the semiconductor device 1 according to the first embodiment, the processes up to the process described with reference to FIGS. 6A and 6B, that is, up to the process of forming the source region 24 are performed.

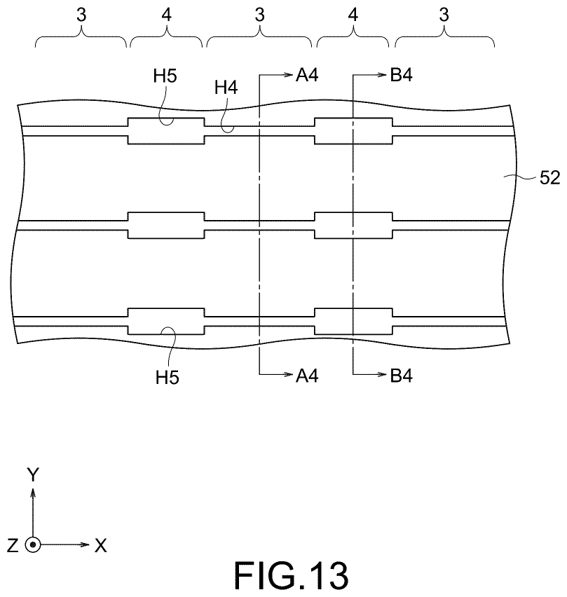

Next, the interlayer insulating film 52 is formed on the upper surface 2b of the semiconductor layer by CVD or the like, as illustrated in FIGS. 12A and 12B. Thereafter, an opening H4, which penetrates the interlayer insulating films 52 and 53, is formed in the FET operation portion 3 and an opening H5, which penetrates the interlayer insulating films 52 and 53, is formed in the non-FET operation portion 4, by RIE or the like. At this time, the width of the opening H5 is made larger than the width of the opening H4. FIG. 13 is a plan view of the interlayer insulating film 52 at the time when the openings H4 and H5 are formed.

Thereafter, a trench, which penetrates the source region 24 exposed at the bottom surface of the opening H4 or H5 to reach the base region 23, is formed in each of the FET operation portion 3 or the non-FET operation portion 4 by RIE or the like. Since the width of the opening H5 is larger than the width of the opening H4, the width of the trench formed in the non-FET operation portion 4 is larger than the width of the trench formed in the FET operation portion 3.

Thereafter, parts of the interlayer insulating films 52 and 53 (sidewalls of the openings H4, H5) are removed by wet etching or the like, whereby the upper portions thereof are expanded in the Y-axis direction. Note that this process may be omitted.

Thereafter, p-type impurities are ion implanted into the upper surface 2b of the semiconductor layer to, whereby the high-concentration region 32 is formed in the FET operation portion 3 and the high-concentration region 42 is formed in the non-FET operation portion 4.

Thereafter, an activation process is performed. The subsequent processes are similar to the manufacturing process of the first embodiment.

Through the above processes, the semiconductor device 1B according to the second embodiment is manufactured.

According to the manufacturing method of the present embodiment, the width of the high-concentration region 42B can be made larger than the width of the high-concentration region 32B by one ion implantation, as described above. Therefore, the semiconductor device 1B can be manufactured with fewer processes than in the first embodiment and the modification of the first embodiment.

In addition, the width of the contact part 43B is larger than the width of the high-concentration region 32B, so that the ratio of the width of the high-concentration region 42B to the width of the high-concentration region 32B can be further increased. As a result, compared to the semiconductor device 1 according to the first embodiment and the semiconductor device 1A according to the modification of the first embodiment, minority carriers accumulated in the base region 23 are more easily injected into the high-concentration region 42B. Therefore, the avalanche breakdown tolerance of the semiconductor device 1B can be further improved.

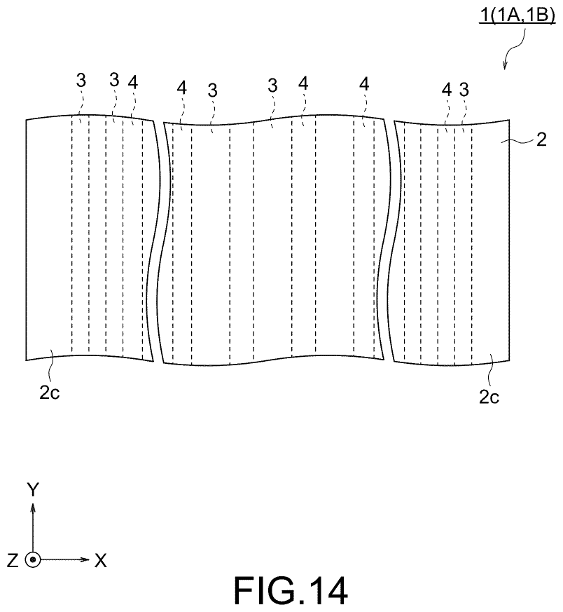

In the semiconductor devices 1, 1A, and 1B described above, the length, in the X-axis direction, of the FET operation portion 3 is larger than the length, in the X-axis direction, of the non-FET operation portion 4, as illustrated in FIGS. 1, 8, and 10. As a result, an influence on the on-resistance of the semiconductor device 1, 1A, or 1B, caused by the provision of the non-FET operation portion 4, can be reduced. Note that, as illustrated in FIG. 14, the ratio of the non-FET operation portion 4 to the FET operation portion 3 may increase as terminal ends (both ends) 2c of the semiconductor layer 2 are approached along the X-axis direction. In particular, the ratio of the length, in the X-axis direction, of the non-FET operation portion 4 to the length, in the X-axis direction, of the FET operation portion 3 may increase as the terminal ends 2c are approached. As a result, the influence on the on-resistance of the semiconductor device 1, 1A, or 1B, caused by the provision of the non-FET operation portion 4, can be more effectively reduced.

In addition, in the semiconductor devices 1, 1A, and 1B described above, the FET operation portion 3 and the non-FET operation portion 4 are provided to be in direct contact with each other. The present invention is not limited thereto, and the FET operation portion 3 and the non-FET operation portion 4 may be provided via another non-FET operation portion. For example, another non-FET operation portion, including a conductive connection part with a width smaller than that of the gate electrode 31 and a high-concentration region with a width that is the same as or smaller than those of the high-concentration regions 32, 32A, and 32B, may be provided between the FET operation portion 3 and the non-FET operation portion 4. As a result, even if the positions of the openings or trenches, in which the contact parts 33, 33A, and 33B and the contact parts 43, 43A, and 43B are provided, are shifted in the X-axis direction, a fluctuation in the threshold voltage can be suppressed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor device comprising:
a semiconductor layer including a first main surface and a second main surface;
a first electrode provided on the first main surface;
a second electrode provided on the second main surface via an interlayer insulating film;
a first semiconductor region of a first conductivity type provided in the semiconductor layer and located on the first electrode;
a second semiconductor region of a second conductivity type provided in the semiconductor layer and located on the first semiconductor region; and
a third semiconductor region of the first conductivity type provided in the semiconductor layer and located between the second semiconductor region and the second electrode, wherein
the semiconductor layer includes a first portion and a second portion that are provided along a second direction orthogonal to a first direction heading from the first electrode to the second electrode,
the first portion includes:
a third electrode provided in the second semiconductor region via an insulating region; and
a fourth semiconductor region of the second conductivity type that is provided in the second semiconductor region, is electrically connected to the second electrode via a first contact part, and has an impurity concentration higher than an impurity concentration of the second semiconductor region, and
the second portion includes:
a conductive connection part provided in the second semiconductor region via an insulating region and electrically connected to the third electrode, a length, in a third direction orthogonal to the first direction and the second direction, of the conductive connection part being smaller than a length, in the third direction, of the third electrode; and
a fifth semiconductor region of the second conductivity type that is provided in the second semiconductor region, is electrically connected to the second electrode via a second contact part, and has an impurity concentration higher than the impurity concentration of the second semiconductor region, a length, in the third direction, of the fifth semiconductor region being larger than a length, in the third direction, of the fourth semiconductor region.

2. The semiconductor device according to claim 1, wherein
the first contact part is provided such that an upper end is connected to the second electrode and a lower end is located closer to the second electrode than an upper end of the second semiconductor region is,
the fourth semiconductor region extends in the third semiconductor region and is connected to the first contact part, and
the second contact part is provided such that an upper end is connected to the second electrode and a lower end is connected to the fifth semiconductor region.

3. The semiconductor device according to claim 2, wherein the first portions and the second portions are alternately provided along the second direction.

4. The semiconductor device according to claim 3, wherein a ratio of the second portion to the first portion increases as both ends of the semiconductor layer are approached along the second direction.

5. The semiconductor device according to claim 2, wherein the impurity concentration of the fifth semiconductor region is higher than the impurity concentration of the fourth semiconductor region.

6. The semiconductor device according to claim 2, further comprising a field plate electrode that is provided in the semiconductor layer via an insulating region, is electrically insulated from the semiconductor layer by the insulating region, and is electrically connected to the second electrode.

7. The semiconductor device according to claim 1, wherein
the first contact part is provided such that an upper end is connected to the second electrode and a lower end is connected to the fourth semiconductor region,
the second contact part is provided such that an upper end is connected to the second electrode and a lower end is connected to the fifth semiconductor region, and
a length, in the third direction, of the second contact part in the third semiconductor region is larger than a length, in the third direction, of the first contact part in the third semiconductor region.

8. The semiconductor device according to claim 7, wherein the first portions and the second portions are alternately provided along the second direction.

9. The semiconductor device according to claim 8, wherein a ratio of the second portion to the first portion increases as both ends of the semiconductor layer are approached along the second direction.

10. The semiconductor device according to claim 7, wherein the impurity concentration of the fifth semiconductor region is higher than the impurity concentration of the fourth semiconductor region.

11. The semiconductor device according to claim 7, further comprising a field plate electrode that is provided in the semiconductor layer via an insulating region, is electrically insulated from the semiconductor layer by the insulating region, and is electrically connected to the second electrode.

12. The semiconductor device according to claim 1, wherein a length, in the second direction, of the first portion in the semiconductor layer is larger than a length, in the second direction, of the second portion in the semiconductor layer.

13. The semiconductor device according to claim 12, wherein the first portions and the second portions are alternately provided along the second direction.

14. The semiconductor device according to claim 13, wherein a ratio of the second portion to the first portion increases as both ends of the semiconductor layer are approached along the second direction.

15. The semiconductor device according to claim 12, wherein the impurity concentration of the fifth semiconductor region is higher than the impurity concentration of the fourth semiconductor region.

16. The semiconductor device according to claim 12, further comprising a field plate electrode that is provided in the semiconductor layer via an insulating region, is electrically insulated from the semiconductor layer by the insulating region, and is electrically connected to the second electrode.

17. The semiconductor device according to claim 1, wherein the first portions and the second portions are alternately provided along the second direction.

18. The semiconductor device according to claim 17, wherein a ratio of the second portion to the first portion increases as both ends of the semiconductor layer are approached along the second direction.

19. The semiconductor device according to claim 1, wherein the impurity concentration of the fifth semiconductor region is higher than the impurity concentration of the fourth semiconductor region.

20. The semiconductor device according to claim 1, wherein
the conductive connection part in the second portion is farther from an interface between the second semiconductor region and the insulating region than the third electrode in the first portion is, and/or
the fourth semiconductor region in the first portion is farther from the interface between the second semiconductor region and the insulating region than the fifth semiconductor region in the second portion is.
